(19) United States
(12) Patent Application Publication
(10) Pub. No.: US 2020/0303632 A1
(43) Pub. Date: Sep. 24, 2020

(54) MAGNETIC DEVICE

(71) Applicant: TOSHIBA MEMORY CORPORATION, Tokyo (JP)

(72) Inventors: Daisuke WATANABE, Yokkaichi Mie (JP); Toshihiko NAGASE, Kuwana Mie (JP); Koji UEDA, Kawasaki Kanagawa (JP); Young Min EEH, Seongnam-si Gyeonggi-do (KR)

(73) Assignee: TOSHIBA MEMORY CORPORATION, Tokyo (JP)

(21) Appl. No.: 16/566,020

(22) Filed: Sep. 10, 2019

(30) Foreign Application Priority Data
Mar. 18, 2019 (JP) 2019-049603

(51) Int. Cl. H01L 43/08; G11C 11/15; H01F 10/32; H01L 27/22; H01F 10/12; H01L 43/02; H01L 43/10; G11C 11/16

(52) U.S. Cl. CPC H01L 43/08; G11C 11/15; H01F 10/3268; H01F 10/3286; B82Y 25/00; H01F 10/126; H01L 43/02; H01L 43/10; G11C 11/161; H01L 27/228

(57) ABSTRACT

According to one embodiment, a magnetic device includes a magnetoresistive effect element. The magnetoresistive effect element includes a first nonmagnet, a second nonmagnet, a first ferromagnet between the first nonmagnet and the second nonmagnet, a third nonmagnet including a rare-earth oxide, the second nonmagnet between the first ferromagnet and the third nonmagnet, and a fourth nonmagnet between the second nonmagnet and the third nonmagnet and including a metal.

### CROSS-REFERENCE TO RELATED APPLICATIONS

This application is based upon and claims the benefit of priority from Japanese Patent Application No. 2019-049603, filed Mar. 18, 2019, the entire contents of which are incorporated herein by reference.

### FIELD

Embodiments described herein relate generally to a magnetic device.

### BACKGROUND

Magnetic devices including magnetic elements are known.

### BRIEF DESCRIPTION OF THE DRAWINGS

FIG. 1 is a block diagram to explain a configuration of a magnetic memory device according to a first embodiment.

FIG. 2 is a circuit diagram to explain a configuration of a memory cell array of the magnetic memory device according to the first embodiment.

FIG. 3 is a cross-sectional view to explain a configuration of the memory cell array of the magnetic memory device according to the first embodiment.

FIG. 4 is a cross-sectional view to explain a configuration of the memory cell array of the magnetic memory device according to the first embodiment.

FIG. 5 is a cross-sectional view to explain a configuration of a magnetoresistive effect element of the magnetic memory device according to the first embodiment.

FIG. 6 is a schematic view to explain a manufacturing method of the magnetoresistive effect element of the magnetic memory device according to the first embodiment.

FIG. 7 is a schematic view to explain a manufacturing method of the magnetoresistive effect element of the magnetic memory device according to the first embodiment.

FIG. 8 is a schematic view to explain effects according to the first embodiment.

FIG. 9 is a schematic view explain a configuration of a memory cell array of a magnetic memory device according to a modification of the first embodiment.

FIG. 10 is a cross-sectional view to explain a configuration of a memory cell of a magnetic memory device according to the modification of the first embodiment.

### DETAILED DESCRIPTION

In general, according to one embodiment, a magnetic device includes a magnetoresistive effect element. The magnetoresistive effect element includes a first nonmagnet, a second nonmagnet, a first ferromagnet between the first nonmagnet and the second nonmagnet, a third nonmagnet including a rare-earth oxide, the second nonmagnet between the first ferromagnet and the third nonmagnet, and a fourth nonmagnet between the second nonmagnet and the third nonmagnet and including a metal.

Hereinafter, the embodiments is described with reference to the drawings. In the description below, structural elements having the same functions and configurations is denoted by a common reference symbol. To distinguish a plurality of structural elements having a common reference symbol from each other, an additional symbol is added after the common reference symbol. If it is unnecessary to distinguish the structural elements, only a common reference symbol is assigned to the structural elements, and no additional symbol is added. Herein, additional symbols are not limited to subscripts or superscripts, and they may be lower-case alphabetical letters added to reference symbols, and indices meaning arrangements.

### 1. First Embodiment

A magnetic device according to a first embodiment is described. The magnetic device according to the first embodiment is, for example, a perpendicular magnetic magnetization-type magnetic memory device in which an element having a magnetoresistive effect provided by a magnetic tunnel junction (MTJ) (such an element may be called an MTJ element or a magnetoresistive effect element) as a resistance change element.

In the following, the magnetic memory device as an example of the magnetic device is explained.

### 1.1 Configuration

First, a configuration of the magnetic memory device according to the first embodiment is described.

### 1.1.1 Configuration of Magnetic Memory Device

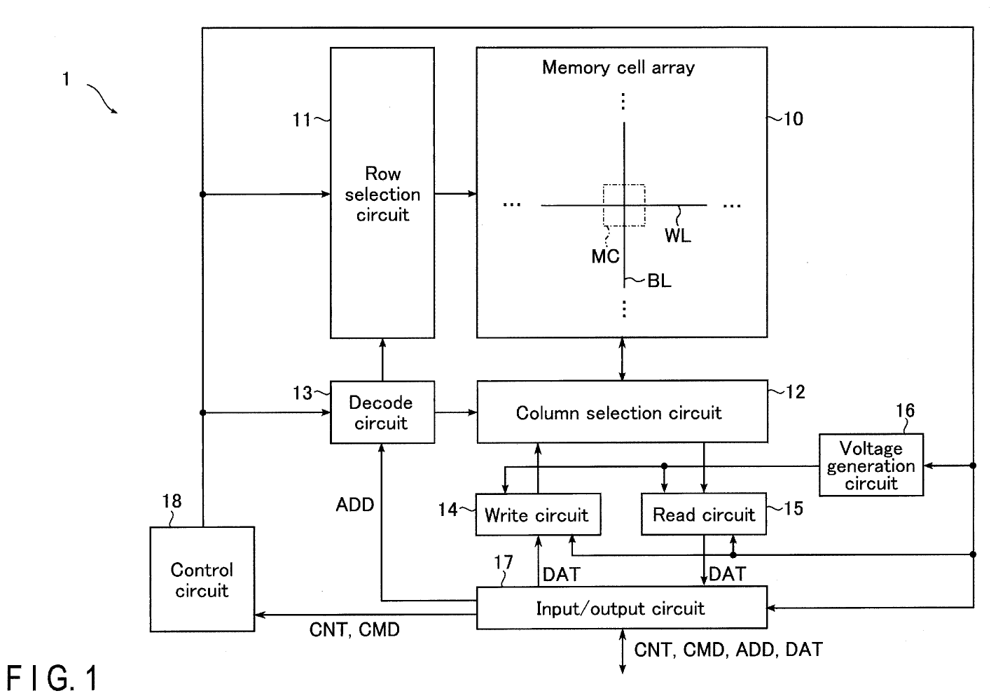

FIG. 1 is a block diagram illustrating a configuration of the magnetic memory device according to the first embodiment. As illustrated in FIG. 1, the magnetic memory device 1 includes a memory cell array 10, a row selection circuit 11, a column selection circuit 12, a decode circuit 13, a write circuit 14, a read circuit 15, a voltage generation circuit 16, an input/output circuit 17, and a control circuit 18.

The memory cell array 10 includes a plurality of memory cells MC, each associated with a row and a column. Memory cells MC arranged in the same row are coupled to the same word line WL, and memory cells MC arranged in the same column are coupled to the same bit line BL.

The row selection circuit 11 is coupled to the memory cell array 10 via word lines WL, To the row selection circuit 11, a decoding result of an address ADD provided from the decode circuit 13 (row address) is supplied. The row selection circuit 11 sets a word line WL corresponding to a row which is selected based on the decoding result of an address ADD to a selected state. Hereinafter, the word line WL that has been set to a selected state is referred to as a selected word line WL. The word lines WL other than the selected word line WL are referred to as non-selected word lines WL.

The column selection circuit 12 is coupled to the memory cell array 10 via bit lines BL. To the column selection circuit 12, a decoding result of an address ADD provided from the decode circuit 13 (column address) is supplied. The column selection circuit 12 sets a column which is selected based on the decoding result of an address ADD to a selected state. Hereinafter, the bit line BL that has been set to a selected state is referred to as a selected bit line BL. The bit lines BL other than the selected bit line BL are referred to as non-selected bit lines BL.

The decode circuit 13 decodes an address ADD from the input/output circuit 17. The decode circuit 13 supplies the decoding result of the address ADD to the row selection circuit 11 and the column selection circuit 12. The address ADD includes an address of a column to be selected and an address of a row to be selected.

The write circuit 14 writes data to a memory cell MC. The write circuit 14 includes, for example, a write driver (not illustrated).

The read circuit 15 reads data from a memory cell MC. The read circuit 15 includes, for example, a sense amplifier (not illustrated).

The voltage generation circuit 16 generates a voltage for various operations of the memory cell array 10 by using a power supply voltage provided outside (not illustrated) of the magnetic memory device 1. For example, the voltage generation circuit 16 generates various voltages required for a write operation, and outputs the voltages to the write circuit 14. The voltage generation circuit 16 also generates various voltages required for a read operation, and outputs the voltages to the read circuit 15.

The input/output circuit 17 transfers an address ADD provided outside of the magnetic memory device 1 to the decode circuit 13. The input/output circuit 17 transfers a command CMD provided outside of the magnetic memory device 1 to the control circuit 18. The input/output circuit 17 transmits and receives various control signals CNT between the outside of the magnetic memory device 1 and the control circuit 18. The input/output circuit 17 transfers data DAT provided outside of the magnetic memory device 1 to the write circuit 14, and outputs data DAT transferred from the read circuit 15 to the outside of the magnetic memory device 1.

The control circuit 18 controls the operations of the row selection circuit 11, the column selection circuit 12, the decode circuit 13, the write circuit 14, the read circuit 15, the voltage generation circuit 16, and the input/output circuit 17 in the magnetic memory device 1 based on a control signal CNT and a command CMD.

### 1.1.2 Configuration of Memory Cell Array

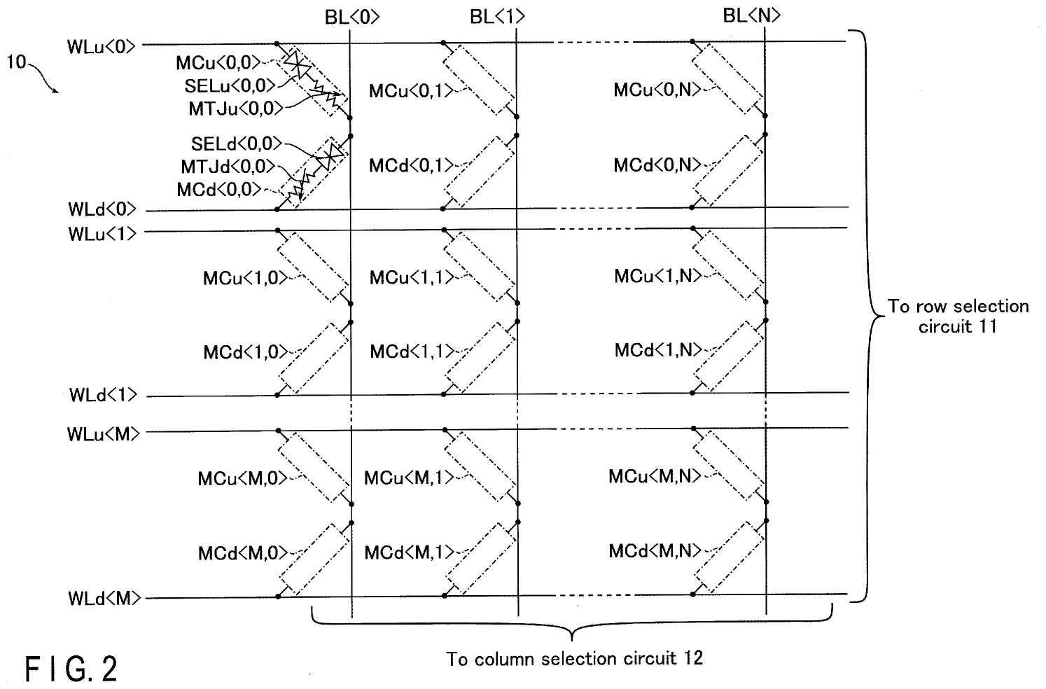

Next, a configuration of the memory cell of the magnetic memory device according to the first embodiment is described with reference to FIG. 2. FIG. 2 is a circuit diagram showing a configuration of the memory cell array of the magnetic memory device according to the first embodiment. In FIG. 2, the word lines WL are classified by additional symbols such as two lower-case alphabets (“u” and “d”) and index (“< >”).

As shown in FIG. 2, the memory cells MC (MCu and Med) are arranged in a matrix in the memory cell array 10, and are respectively associated with a set of one of a plurality of bit lines BL (BL<0>, BL<1>, . . . , BL<N>) and one of a plurality of word lines WLd (WLd<0>, WLd<1>, . . . , WLd<M>) or WLu<0>, WLu<1>, . . . , WLu<M>) (M and N are integers). In other words, the memory cell MCd<i,j> (0≤i≤M, 0≤j≤N) is coupled between the word line WLd<i> and the bit line BL<j>, and the memory cell MCu<i,j> is coupled between the word line WLu<i> and the bit line BL<j>.

The additional symbols “d” and “u” are used for convenience to identify a memory cell of the memory cells that is provided below or above a bit line BL. An example of a three-dimensional configuration of the memory cell array 10 is described later in detail.

The memory cell MCd<i,j> includes a switching element SELd<i,j> and a magnetoresistive effect element MTJd<i,j> coupled in series thereto. The memory cell MCu<i,j> includes a switching element SELu<i,j> and a magnetoresistive effect element MTJu<i,j> coupled in series thereto.

The switching element SEL has a function as a switch that controls a supply of a current to a corresponding magnetoresistive effect element MTJ when data is read from and written to the magnetoresistive effect element MTJ. More specifically, the switching element SEL in a memory cell MC, for example, serves as an insulator having a large resistance value and cuts off a current (in other words, is in an off state) when a voltage applied to the memory cell MC is below a threshold voltage Vth, and serves as a conductor having a small resistance value and allows a current to flow (in other words, is in an on state) when the voltage exceeds the threshold voltage Vth. In other words, the switching element SEL has a function of switching between the on state and the off state in accordance with a voltage applied to the memory cell MC, irrespective of a direction of a flowing current.

The switching element SEL may be, for example, a two-terminal type switching element having only two terminals. When a voltage applied between the two terminals is smaller than a threshold voltage, the switching element is in a “high resistance” state, such as an electrically non-conductive state. When a voltage applied between the two terminals is equal to or larger than the threshold voltage, the switching element is in a “low resistance” state, such as an electrically conductive state. The switching element may have this function regardless of the polarity of the voltage. For example, the switching element may include at least one type of chalcogen selected from a group of tellurium (Te), selenium (Se), and sulfur (S). Alternatively, the switching element may include chalcogenide, which is a compound containing the chalcogen element. This switching element may include at least one element selected from a group consisting of boron (B), aluminum (Al), gallium (Ga), indium (In), carbon (C), silicon (Si), germanium (Ge), tin (Sn), arsenic (As), phosphorus (P), antimony (Sb), titanium (Ti), and bismuth (Bi). More specifically, the switching element may include at least two elements selected from germanium (Ge), antimony (Sb), tellurium (Te), titanium (Ti), arsenic (As), indium (In), and bismuth (Bi). Furthermore, the switching element may include an oxide of at least one element selected from Ti, vanadium (V), chromium (Cr), niobium (Nb), molybdenum (Mo), hafnium (Hf), and tungsten (W).

A resistance value of the magnetoresistive effect element MTJ can be switched between a low-resistance state and a high-resistance state by a current of which the control is selected by the switching element SEL. The magnetoresistive effect element MTJ is capable of writing data in accordance with the change of its resistance state, and stores written data in a non-volatile manner to function as a readable memory element.

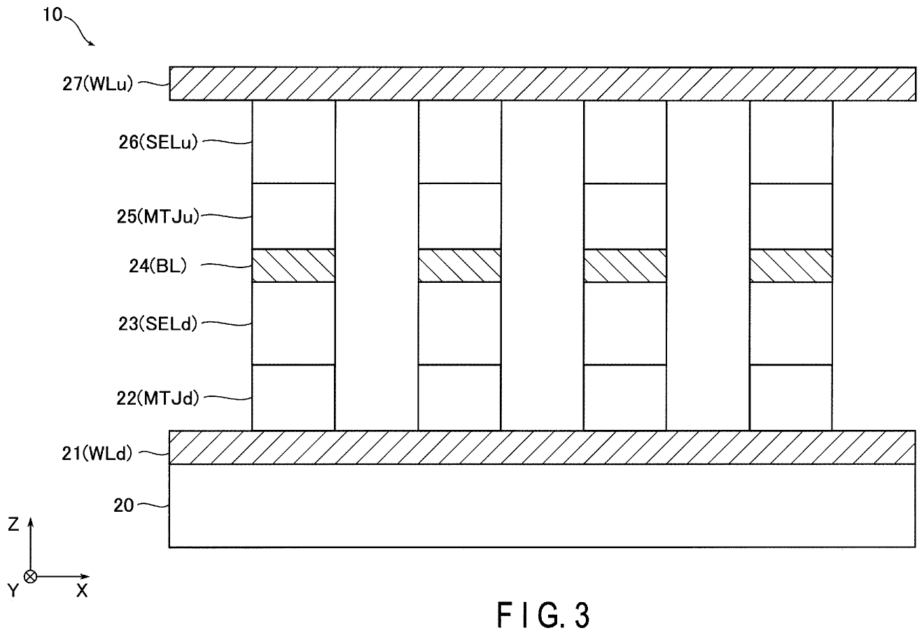

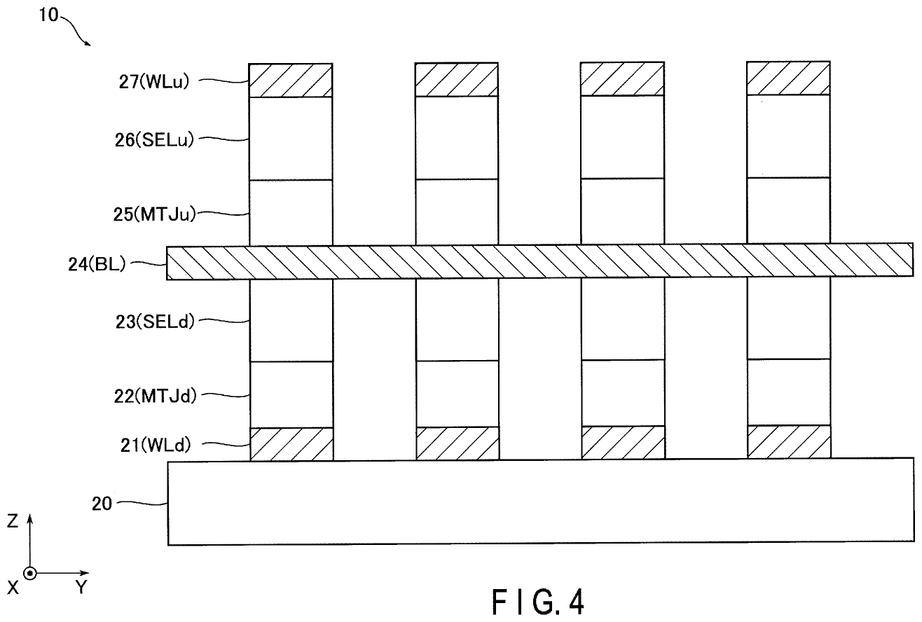

Next, a cross-section structure of the memory cell array 10 is described with reference to FIG. 3 and FIG. 4. FIG. 3 and FIG. 4 show examples of cross sectional views illustrating a configuration of the memory cell array of the magnetic memory device according to the first embodiment. FIG. 3 and FIG. 4 show cross sections of the memory cell array 10 viewed from different directions intersecting each other.

As shown in FIG. 3 and FIG. 4, the memory cell array 10 is disposed above a semiconductor substrate 20. In the following description, a plane parallel to the surface of the semiconductor substrate 20 is defined as an XY plane, and a direction perpendicular to the XY plane is defined as a Z direction. The direction along the word lines WL is defined as an X direction, and the direction along the bit lines BL is defined as a Y direction. Thus, FIG. 3 and FIG. 4 are cross sectional views of the memory cell array 10, taken along the Y direction and the X direction, respectively.

For example, a plurality of conductors 21 are disposed on an upper surface of the semiconductor substrate 20. The conductors 21 have conductivity and each functions as a word line W1d. The plurality of conductors 21 are, for example, arranged in the Y direction, and each extending in the X direction. Although FIG. 3 and FIG. 4 illustrate a case in which the conductors 21 are disposed on the semiconductor substrate 20, the embodiment is not limited to this case. For example, the conductors 21 may be disposed above the semiconductor 20, not in contact with but apart from the semiconductor 20.

On the upper surface of one conductor 21, a plurality elements 22, each functioning as a magnetoresistive effect element MTJd, are disposed. The elements 22 disposed on the upper surface of the conductor 21 are, for example, arranged in the X direction. In other words, the elements 22 arranged in line in the X direction are coupled to the upper surface of one conductor 21 in common. The details of the configuration of the elements 22 is described later.

On upper surfaces of the respective elements 22, elements 23 that function as switching elements SELd are disposed. Each of upper surfaces of the elements 23 is coupled to any one of a plurality of conductors 24. The conductors 24 have conductivity and each functions as a bit line BL. The conductors 24 are, for example, arranged in the X direction, and each extending in the Y direction. In other words, the elements 23 arranged in line along the Y direction are coupled to one conductor 24 in common. Although FIG. 3 and FIG. 4 illustrate a case in which each of the elements 23 is disposed on the element 22 and the conductor 24, the embodiment is not limited to this case. For example, each of the elements 23 may be coupled to the element 22 and the conductor 24 via a conductive contact plug (not shown).

On an upper surface of one conductor 24, a plurality of elements 25, each functioning as a magnetoresistive effect element MTJu, are disposed. The elements 25 disposed on the upper surface of the conductor 24 are, for example, arranged in the Y direction. In other words, the elements 25 arranged in line along the Y direction are coupled to the upper surface of one conductor 24 in common. The elements 25 have a configuration equivalent to that of the elements 22, for example.

On upper surfaces of the respective elements 25, elements 26 that function as switching elements SELu are provided. Each of upper surfaces of the elements 26 is coupled to any one of a plurality of conductors 27. The conductors 27 have conductivity and each functions as a word line WLu. The conductors 27 are, for example, arranged in the Y direction, and each extending in the X direction. In other words, the plurality of elements 26 arranged in line in the X direction are coupled to one conductor 27 in common. Although FIG. 3 and FIG. 4 illustrate a case in which each of the conductors 26 is disposed on the element 25 and the conductor 27, the embodiment is not limited to this case. For example, each of the elements 26 may be coupled to the element 25 and the conductor 27 via a conductive contact plug (not shown).

The memory cell array 10 configured as described above has a structure in which a set of two word lines, WLd and WLu, corresponds to one bit line BL. Furthermore, the memory cell array 10 has a structure including a plurality of memory cells MC at different heights in the Z direction; in the structure, a memory cell MCd is arranged between a word line WLd and a bit line BL and a memory cell MCu is arranged between a bit line BL and a word line WLu. In the cell structure illustrated in FIG. 3 and FIG. 4, the memory cell MCd is associated with the lower layer and the memory cell MCu is associated with the upper layer. In other words, of two memory cells MC coupled to one bit line BL in common, the memory cell MC disposed in the upper layer of the hit line BL is referred to with the additional symbol “u”, as “memory cell MCu”, and the other memory cell MC disposed in the lower layer is referred to with “d”, as “memory cell MCd”.

### 1.1.3 Magnetoresistive Effect Element

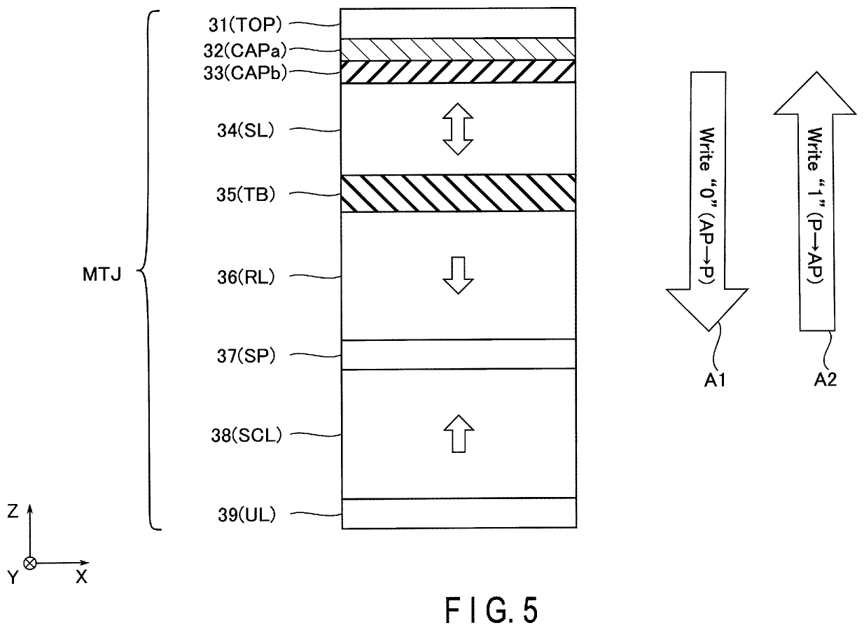

Next, a configuration of the magnetoresistive effect element of the magnetic device according to the first embodiment is described with reference to FIG. 5. FIG. 5 is a cross-sectional view illustrating a configuration of the magnetoresistive effect element of the magnetic device according to the first embodiment. FIG. 5 shows an example of a cross section of the magnetoresistive effect element MTJd shown in FIG. 3 and FIG. 4, taken along a plane perpendicular in the Z direction (e.g., the YZ plane). Since the magnetoresistive effect element MTJu has a configuration similar to that of the magnetoresistive effect element MTJd, the illustration is omitted.

As shown in FIG. 5, the magnetoresistive effect element MTJ includes, for example, a nonmagnet 31 serving as a top layer TOP, a nonmagnet 32 serving as a capping layer CAPa, a nonmagnet 33 serving as a capping layer CAPb, a ferromagnet 34 serving as a storage layer SL, a nonmagnet 35 serving as a tunnel barrier layer TB, a ferromagnet 36 serving as a reference layer RL, a nonmagnet 37 serving as a spacer layer SP, a ferromagnet 38 serving as a shift cancelling layer SCL, and a nonmagnet 39 serving as an under layer UL.

In the magnetoresistive effect element MTJd, the nonmagnet 39, the ferromagnet 38, the nonmagnet 37, the ferromagnet 36, the nonmagnet 35, the ferromagnet 34, the nonmagnet 33, the nonmagnet 32, and the ferromagnet 31 are stacked in this order, from the word line WLd side toward the bit line BL side (in the direction of the Z axis). In the magnetoresistive effect element MTJu, the nonmagnet 39, the ferromagnet 38, the nonmagnet 37, the ferromagnet 36, the nonmagnet 35, the ferromagnet 34, the nonmagnet 33, the nonmagnet 32, and the ferromagnet 31 are stacked in this order, from the bit line BL side toward the word line WLu side (in the direction of the Z axis). The magnetoresistive effect elements MTJd and MTJu function as, for example, perpendicular magnetization type MTJ elements, in which each of the magnetization directions of the magnets that constitute the magnetoresistive effect elements MTJd and MTJu is oriented in a direction perpendicular with respect to a film surface. The magnetoresistive effect element MTJ may further include an additional layer between two of the aforementioned layers 31 to 39.

The nonmagnet 31 is a non-magnetic rare-earth oxide, and has a function of absorbing elements, such as boron (B), diffusing from the ferromagnet 34 during the process of producing the magnetoresistive effect element MTJ. The nonmagnet 31 includes an oxide of at least one rare-earth material selected from yttrium (Y), lanthanum (La), cerium (Ce), praseodymium (Pr), neodymium (Nd), promethium (Pm), samarium (Sm), scandium (Sc), europium (Eu), gadolinium (Gd), terbium (Tb), dysprosium (Dy), holmium (Ho), erbium (Er), thulium (Tm), ytterbium (Yb), and lutetium (Lu). Furthermore, the nonmagnet 31 may include boron (B) as an element absorbed from the ferromagnet 34.

The nonmagnet 32 is a conductive film of a nonmagnetic metal, and has a function of suppressing an increase of a parasitic resistance of the magnetoresistive effect element MTJ. The resistance value of the nonmagnet 32 is preferably, for example, a tenth or less of the resistance of the nonmagnet 35, to suppress the increase of a parasitic resistance. Furthermore, the nonmagnet 31 is preferably disposed near the ferromagnet 34 so as not to reduce the effect of absorbing boron (B) from the ferromagnet 34. Accordingly, to minimize the distance between the ferromagnet 34 and the nonmagnet 31, the thickness of the nonmagnet 32 is preferably 2 nm (nanometers) or smaller.

Furthermore, the nonmagnet 32 preferably does not interfere with the function of the nonmagnet 31 absorbing boron (B) from the ferromagnet 34. In other words, the nonmagnet 32 is preferably a material that can easily be boronized.

As materials that satisfy the requirements described above, the nonmagnet 32 may include at least one metal selected from, for example, tantalum (Ta), hafnium (Hf), zirconium (Zr), titanium (Ti), vanadium (V), and niobium (Nb).

The nonmagnet 33 is a non-magnetic insulating film, and includes, for example, magnesium oxide (MgO). The nonmagnet 33 may have a crystalline structure of a body-centered cubic (bcc) type (an NaCl crystalline structure having (001) planar orientation). In a crystallization treatment of the ferromagnet 34 adjacent to the nonmagnet 33, the nonmagnet 33 functions as a seed material to be a nucleus for developing a crystalline film from the interface with the ferromagnet 34.

A lattice spacing in the nonmagnet 33 is smaller than that in an oxide of a rare-earth element, for example. Therefore, the nonmagnet 33 does not prevent an element having a relatively small covalent radius (for example, boron (B) in the ferromagnet 34) from diffusing into the nonmagnet 31 from the ferromagnet 34. On the other hand, the nonmagnet 33 has a function of preventing an element having a relatively large covalent radius (for example, iron (Fe) in the ferromagnet 34) from diffusing.

To suppress an increase of a parasitic resistance and minimize the distance between the nonmagnet 31 and the ferromagnet 34, the nonmagnet 33 is preferably thinner than, for example, the nonmagnet 35, more specifically, 1 nm (nanometer) or thinner.

The ferromagnet 34 has ferromagnetic properties, and has an axis of easy magnetization in a direction perpendicular to a film surface. The ferromagnet 34 has a magnetization direction oriented toward the bit line BL side or the word line WL side. The ferromagnet 34 includes at least one of iron (Fe), cobalt (Co), and nickel (Ni). The ferromagnet 34 may further include at least one of boron (B), phosphorus (P), carbon (C), aluminum (Al), silicon (Si), tantalum (Ta), molybdenum (Mo), chromium hafnium (Hf), tungsten (W), and titanium (Ti). More specifically, the ferromagnet 34 includes, for example, cobalt-iron-boron (CoFeB) or iron boride (FeB), and may have a crystalline structure of a body-centered cubic (bcc) type.

The nonmagnet 35 is a non-magnetic insulating film, and includes, for example, magnesium oxide (MgO). The nonmagnet 35 may have a crystalline structure of a body-centered cubic (bcc) type (an NaCl crystalline structure having (001) planar orientation). In a crystallization treatment of the ferromagnet 34 adjacent to the nonmagnet 35, as well as the nonmagnet 33, the nonmagnet 35 functions as a seed material to be a nucleus for developing a crystalline film from the interface with the ferromagnet 34. The nonmagnet 35 is arranged between the ferromagnet 34 and the ferromagnet 36, and constitutes a magnetic tunnel junction together with the two ferromagnets.

The ferromagnet 36 has ferromagnetic properties, and has an axis of easy magnetization in a direction perpendicular to a film surface. The ferromagnet 36 has a magnetization direction oriented toward the bit line BL side or the word line WL side. The ferromagnet 36 includes at least one of iron (Fe), cobalt (Co), and nickel (Ni), for example. The ferromagnet 36 may further include at least one of boron (B), phosphorus (P), carbon (C), aluminum (Al), silicon (Si), tantalum (Ta), molybdenum (Mo), chromium (Cr), hafnium (Hf), tungsten (W), and titanium (Ti). The ferromagnet 36 includes, for example, cobalt-iron-boron (CoFeB) or iron boride (FeB), and may have a crystalline structure of a body-centered cubic (bcc) type. The magnetization direction of the ferromagnet 36 is fixed, and in the example of FIG. 5, the magnetization direction is oriented to the ferromagnet 38. In this description, “a magnetization direction is fixed” means that the magnetization direction is not changed by an electric current (spin torque) of such a magnitude that the magnetization direction of the ferromagnet 34 can be reversed.

Although the illustration is omitted in FIG. 5, the ferromagnet 36 may be a multi-layered body including multiple films. Specifically, the multi-layered body that constitutes the ferromagnet 36 may have a structure in which an additional ferromagnet is stacked on a surface of the ferromagnet 38 side of an interface layer containing cobalt-iron-boron (CoFeB) or iron boride (FeB), with a non-magnetic conductor being interposed between the ferromagnet 38 and the additional ferromagnet. The non-magnetic conductor in the multi-layered body constituting the ferromagnet 36 may include at least one metal selected from, for example, tantalum (Ta), hafnium (Hf), tungsten (W), zirconium (Zr), molybdenum (Mo), niobium (Nb), and titanium (Ti). The additional ferromagnet in the multi-layered body constituting the ferromagnet 36 may include at least one structure selected from, for example, a multi-layered film made of cobalt (Co) and platinum (Pt) (i.e., Co/Pt multi-layered film), a multi-layered film made of Co and nickel (Ni) (i.e., Co/Ni multi-layered film), and a multi-layered film made of Co and palladium (Pd) (i.e., Co/Pd multi-layered film).

The nonmagnet 37 is a non-magnetic conductive film, and includes at least one element selected from, for example, ruthenium (Ru), osmium (Os), iridium (Ir), vanadium (V), and chromium (Cr).

The ferromagnet 38 has ferromagnetic properties, and has an axis of easy magnetization in a direction perpendicular to a film surface. The ferromagnet 38 includes at least one alloy selected from, for example, cobalt platinum (CoPt), cobalt nickel (Coni), and cobalt palladium (Coed). The ferromagnet 38 may be a multi-layered body including multiple layers, similarly to the ferromagnet 36. In this case, the ferromagnet 38 may include at least one structure selected from, for example, a multi-layered film made of cobalt (Co) and platinum (Pt) (i.e., Co/Pt multi-layered film), a multi-layered film made of Co and nickel (Ni) (i.e., Co/Ni multi-layered film), and a multi-layered film made of Co and palladium (Pd) (i.e., Co/Pd multi-layered film).

The ferromagnet 38 has a magnetization direction oriented toward the bit line BL side or the word line WL side. The magnetization direction of the ferromagnet 38 is fixed, as well as the ferromagnet 36, and in the example of FIG. 5, the magnetization direction is oriented to the ferromagnet 36.

The ferromagnets 36 and 38 are coupled in an anti-ferromagnetic manner by the nonmagnet 37. In other words, the ferromagnets 36 and 38 are coupled in a manner in which they have magnetization directions mutually-antiparallel. For this reason, in the example illustrated in FIG. 5, the magnetization directions of the ferromagnets 36 and 38 are opposite to each other. Such a bonding structure of the above-described ferromagnet 36, nonmagnet 37, and ferromagnet 38 is called a synthetic anti-ferromagnetic (SAF) structure. It is thereby possible for the ferromagnet 38 to cancel an influence of the stray field of the ferromagnet 36 upon the magnetization direction of the ferromagnet 34. For this reason, it is possible to suppress an occurrence of asymmetry in the susceptibility to magnetization reversal of the ferromagnet 34 (in other words, difference in the susceptibility to reversal of a magnetization direction of the ferromagnet 34 between the reversal in a certain direction and the reversal in the opposite direction) caused by external factors due to stray field, etc. of the ferromagnetic material 36.

The nonmagnet 39 is a nonmagnetic conductive film, and has a function of improving the electrical connectivity with respect to a bit line BL or a word line WL. The nonmagnet 39 includes, for example, a high-melting point metal. The high-melting-point metal refers to a material having a melting point higher than that of iron (Fe) and cobalt (Co); for example, at least one selected from zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

In the first embodiment, a spin injection write method is adopted, and the method includes supplying a write current directly to such a magnetoresistive effect element MTJ, injecting spin torque into the storage layer SL and the reference layer RL by this write current, and controlling the magnetization direction of the storage layer SL and the magnetization direction of the reference layer RL. The magnetoresistive effect element MTJ can take one of a low-resistance state and a high-resistance state, depending on whether the magnetization directions of the storage layer SL and the reference layer RL are parallel or antiparallel.

If a write current Iw0 of a certain amplitude is supplied to the magnetoresistive effect element MTJ in the direction indicated by arrow A1 in FIG. 5, i.e., from the storage layer SL to the reference layer RL, the relationship between the magnetization directions of the storage layer SL and the reference layer RL becomes parallel. In this parallel state, the resistance value of the magnetoresistive effect element MTJ is the lowest, and the magnetoresistive effect element MTJ is set to a low-resistance state. This low-resistance state is called a “P (parallel) state”, and is defined as a data “0” state.

If a write current Iw1 larger than the write current Iw0 is supplied to the magnetoresistive effect element MTJ in the direction indicated by arrow A2 in FIG. 5, i.e., from the reference layer RL to the storage layer SL (the direction opposite to arrow A1), the relationship between the magnetization directions of the storage layer SL and the reference layer RL becomes antiparallel. In this antiparallel state, the resistance value of the magnetoresistive effect element MTJ is the greatest, and the magnetoresistive element MTJ is set to a high-resistance state. This high-resistance state is called “AP (anti-parallel) state”, and is defined as a data “1” state.

The following description is given pursuant to the above-described data-defining method; however, how data “1” and data “0” are defined is not limited to the above-described example. For example, the P state may be defined as data “1”, and the AP state may be defined as data “0”.

### 1.2 Method for Manufacturing Magnetoresistive Effect Element

Next, a method for manufacturing the magnetoresistive effect element of the magnetic memory device according to the first embodiment is described. In the following description, a method for manufacturing the ferromagnet 34 (the storage layer SL) among the structural elements in the magnetoresistive effect element MTJ is specifically described, and a description of the other structural elements (the reference layer RL, the shift cancelling layer SGL, etc.) are omitted.

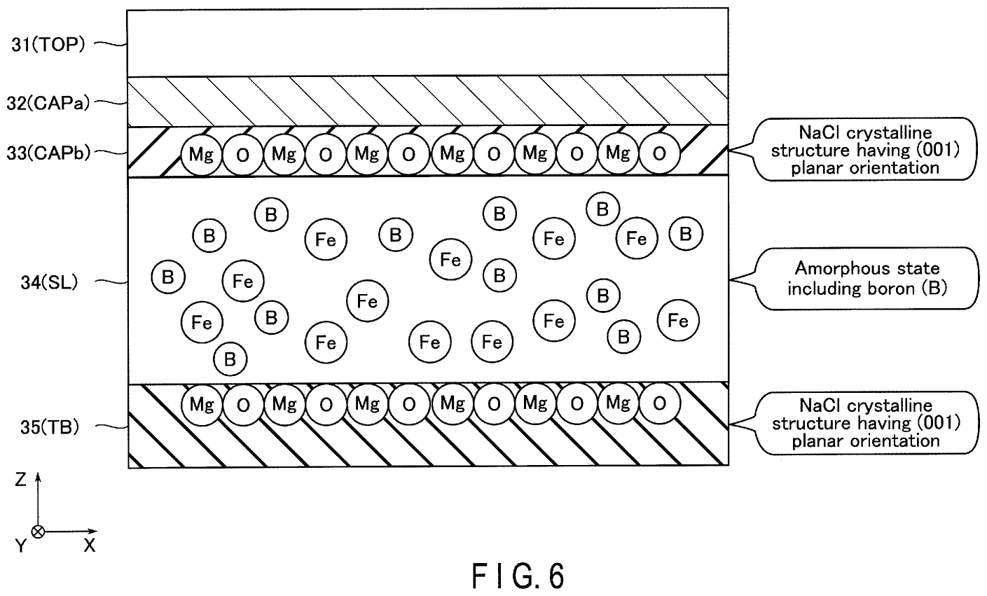

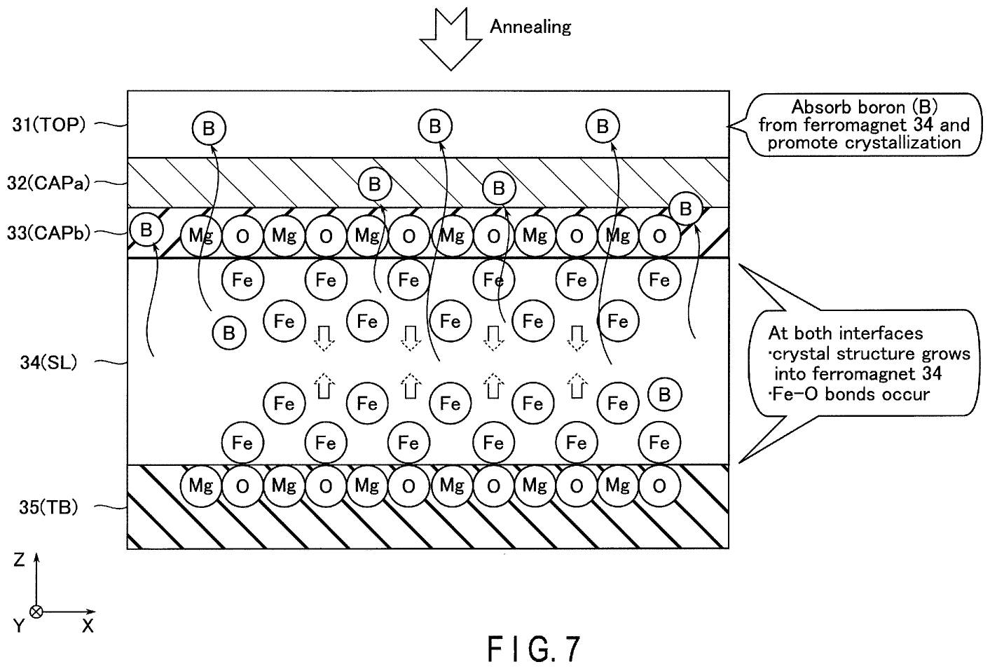

FIG. 6 and FIG. 7 are schematic views illustrating the method for manufacturing the magnetoresistive effect element of the magnetic memory device according to the first embodiment. FIG. 6 and FIG. 7 show a process in which the ferromagnet 34 is changed from an amorphous state to a crystal state by an annealing treatment. The ferromagnet 36, the nonmagnet 37, the ferromagnet 38, and the nonmagnet 39, which are stacked under the nonmagnet 35, are not shown for simplicity.

As shown in FIG. 6, the nonmagnet 35, the ferromagnet 34, the nonmagnet 33, the nonmagnet 32, and the nonmagnet 31 are stacked in this order from the semiconductor substrate 20.

The nonmagnets 35 and 33 have the NaCl crystalline structure having a (001) planar orientation. Accordingly, in the nonmagnets 35 and 33, magnesium (Mg) and oxygen (O) are alternately arrayed at the interfaces with the ferromagnet 34.

The ferromagnet 34 is stacked as an amorphous layer including, for example, iron (Fe) and boron (B).

Next, as shown in FIG. 7, the annealing treatment is performed on each layer stacked as shown in FIG. 6. Specifically, the ferromagnet 34 is transformed from amorphous to crystalline by applying heat to each layer from outside. Here, the nonmagnets 35 and 33 function to control the orientation of the crystalline structure of the ferromagnet 34. In other words, the ferromagnet 34 develops its crystalline structure by using the nonmagnets 35 and 33 as a seed material (a crystallization treatment). Since a mismatch in lattice spacing between iron (Fe) in the ferromagnet 34 and magnesium oxide (MgO) is small, the crystalline structure of ferromagnet 34 is oriented in the same crystal plane as the nonmagnets 35 and 33. As a result, the crystalline orientation of the ferromagnet 34 can be improved and a greater tunnel magnetoresistive ratio (TMR) can be obtained.

Furthermore, at the interfaces between the ferromagnet 34 and each of the nonmagnets 35 and 33, iron (Fe) in the ferromagnet 34 and oxygen (O) in the nonmagnets 35 and 33 are bonded to form an sp hybrid orbital. As a result, the ferromagnet 34 can develop a magnetic anisotropy in the vertical direction from both interfaces.

In the annealing treatment, the nonmagnet 31 absorbs boron (B) from the ferromagnet 34. This promotes crystallization of the ferromagnet 34. As described above, the thickness of the nonmagnet 32 is set to 2 nm (nanometers) or less, and the thickness of the nonmagnet 33 is set to 1 nm (nanometer) or less. Thus, the distance between the nonmagnet 31 and the ferromagnet 34 can be small, so that the nonmagnet 31 can absorb boron (B) from the ferromagnet 34. This contributes to the promotion of the crystallization of the ferromagnet 34.

Furthermore, a material that can be easily boronized is selected as the nonmagnet 32. Therefore, the nonmagnet 32 can also promote the absorption of boron (B) from the ferromagnet 34 together with the nonmagnet 31.

Thus, the manufacturing of the magnetoresistive effect element MTJ is ended.

### 1.3 Advantages of Present Embodiment

According to the first embodiment, the magnetoresistive effect element can improve the perpendicular magnetic anisotropy, while suppressing an increase of the parasitic resistance. This advantage is described below.

In the magnetoresistive effect element MTJ of the first embodiment, the nonmagnet 35, the ferromagnet 34, the nonmagnet 33, the nonmagnet 32, and the nonmagnet 31 are stacked in this order above the semiconductor substrate 20. The nonmagnet 31 includes a rare-earth oxide. Accordingly, boron (B) included in the ferromagnet 34 is absorbed by the nonmagnet 31 during the annealing treatment. As a result, high-quality crystallization of the ferromagnet 34 can be achieved.

Also, the nonmagnets 33 and 35 include magnesium oxide (MgO). Therefore, in the ferromagnet 34, the crystalline structure can grow from both the interface with the nonmagnet 33 and the interface with the nonmagnet 35. Therefore, iron (Fe)-oxygen (O) bonds, which improve the magnetic anisotropy, can be generated at both interfaces.

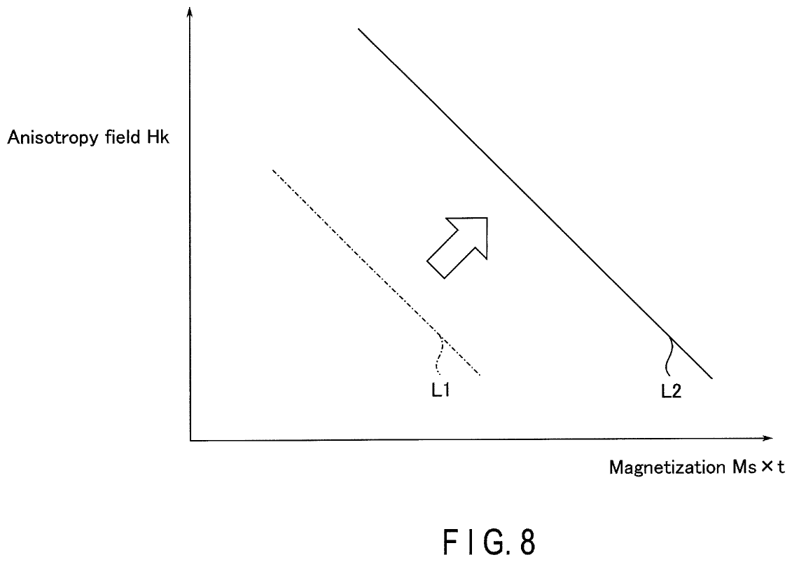

FIG. 8 is a schematic view illustrating effects according to the first embodiment. In FIG. 8, the horizontal axis represents the magnitude of magnetization (Ms×t) and the vertical axis represents the magnitude of an anisotropy field (Hk), based on which the magnitude of perpendicular magnetic anisotropy of a ferromagnet is indicated. Ms and t respectively represent a saturated magnetization and a film thickness of a subject ferromagnet. The magnitude of magnetization (Ms×t) is a product of the saturated magnetization and the film thickness. The perpendicular magnetic anisotropy is correlated to a product of a magnetization and an anisotropy field. Therefore, in the example shown in FIG. 8, as the line is nearer to an upper right corner, this represents greater perpendicular magnetic anisotropy.

FIG. 8 shows a line L1 representing the magnitude of the perpendicular magnetic anisotropy of a ferromagnet of a comparative example, and a line L2 representing the magnitude of the perpendicular magnetic anisotropy of the ferromagnet 34 according to the first embodiment. In the comparative example, a nonmagnet which includes magnesium oxide (MgO) is disposed on only one of the upper and lower surfaces of the ferromagnet. As shown in FIG. 8, the ferromagnet 34 of the first embodiment has greater perpendicular magnetic anisotropy than the ferromagnet of the comparative example. This is because the iron (Fe)-oxygen (O) bonds occur at only one of the upper and lower surfaces of the ferromagnet of the comparative example, whereas the bonds occur at both the upper and lower surfaces of the ferromagnet 34 of the first embodiment. Thus, the ferromagnet 34 of the first embodiment can provide perpendicular magnetic anisotropy theoretically about twice as high as the ferromagnet of the comparative example.

The thicknesses of the nonmagnets 32 and 33 are set smaller than 2 nm (nanometers) and 1 nm (nanometer), respectively. Accordingly, the distance between the nonmagnet 31 and the ferromagnet 34 can be small. Thus, high perpendicular magnetic anisotropy is obtained, while the effect of absorbing boron (B) from the ferromagnet 34 during the annealing treatment is also obtained.

Furthermore, a material that can be easily boronized is selected as the nonmagnet 32. Therefore, reduction of the effect of absorbing boron (B) is suppressed though the nonmagnet 32 is interposed between the nonmagnet 31 and the ferromagnet 34.

Moreover, a material having a resistance value of a tenth or less of the resistance of the nonmagnet 35 is selected as the nonmagnet 32. Therefore, it is possible to suppress the increase of the parasitic resistance due to stacking of the nonmagnet 33 which includes magnesium oxide (MgO) with a relatively high resistance value. As a result, the increase of the resistance value of the magnetoresistive effect element MTJ can be suppressed, and accordingly, the increase of the write current Iw0 and Iw1 can be suppressed. Therefore, the magnetoresistive effect element MTJ can be easily applied to a magnetic memory device.

Further, the ferromagnet 34 is disposed above the ferromagnet 36. The nonmagnet 33 is disposed under the nonmagnet 32. Therefore, the magnetoresistive effect element MTJ is formed to have a structure in which the nonmagnet 33 is stacked on the upper surface of the ferromagnet 34, and so that the nonmagnet 33 has a bcc crystal structure.

If the ferromagnet 34 is disposed under the ferromagnet 36, the nonmagnet 33 is disposed above the nonmagnet 32. More specifically, the nonmagnet 33 is disposed on the upper surface of the nonmagnet 32. In this case, since the nonmagnet 32 does not contain boron (B) at the start of film forming, it can prevent the nonmagnet 33 from having a bcc crystal structure. Thus, it is preferable that the nonmagnet 33 be disposed under the nonmagnet 32. According to the first embodiment, since the magnetoresistive effect element MTJ has a top free structure, the nonmagnet 33 is disposed under the nonmagnet 32, so that the nonmagnet 33 may function as a seed material.

### 2. Modification Etc.

The first embodiment is not limited to the above-mentioned example, and can be modified in various ways. In the following, modifications applicable to the first embodiment is described. For convenience of explanation, differences from the first embodiment is mainly explained.

In the memory cell MC of the first embodiment described above, a two-terminal type switching element is applied as the switching element SEL. However, a metal oxide semiconductor (MOS) may be applied as the switching element SEL. Thus, the memory cell array is not limited to the structure having a plurality of memory cells MC at different heights in the Z direction, but may be of any array structure.

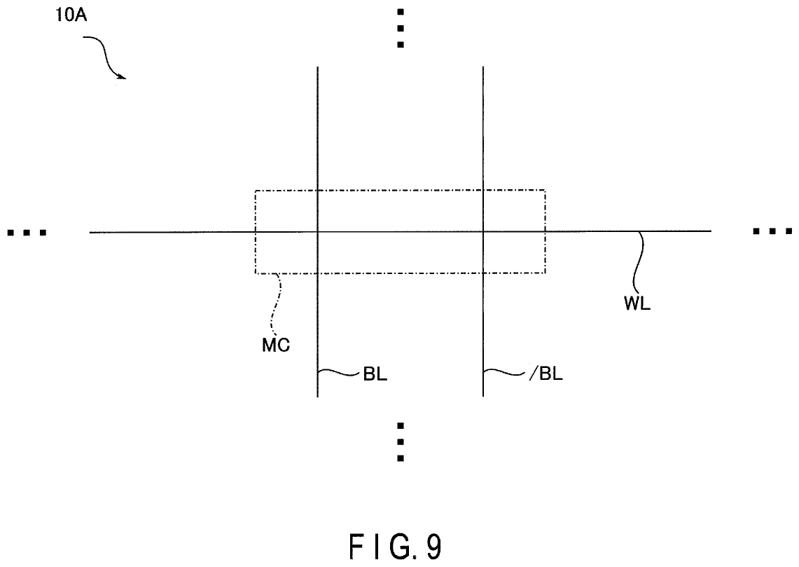

FIG. 9 is a circuit diagram illustrating a configuration of a memory cell array of a magnetic memory device according to a modification. FIG. 9 shows a structure corresponding to the memory cell array 10 of the magnetic memory device 1 of the first embodiment shown in FIG. 1.

The memory cell array 10A shown in FIG. 9 includes a plurality of memory cells MC, each associated with a row and a column. The memory cells MC arranged in the same row are coupled to the same word line WL, and both ends of each of the memory cells MC arranged in the same column are coupled to the same bit line BL and the same source line /BL.

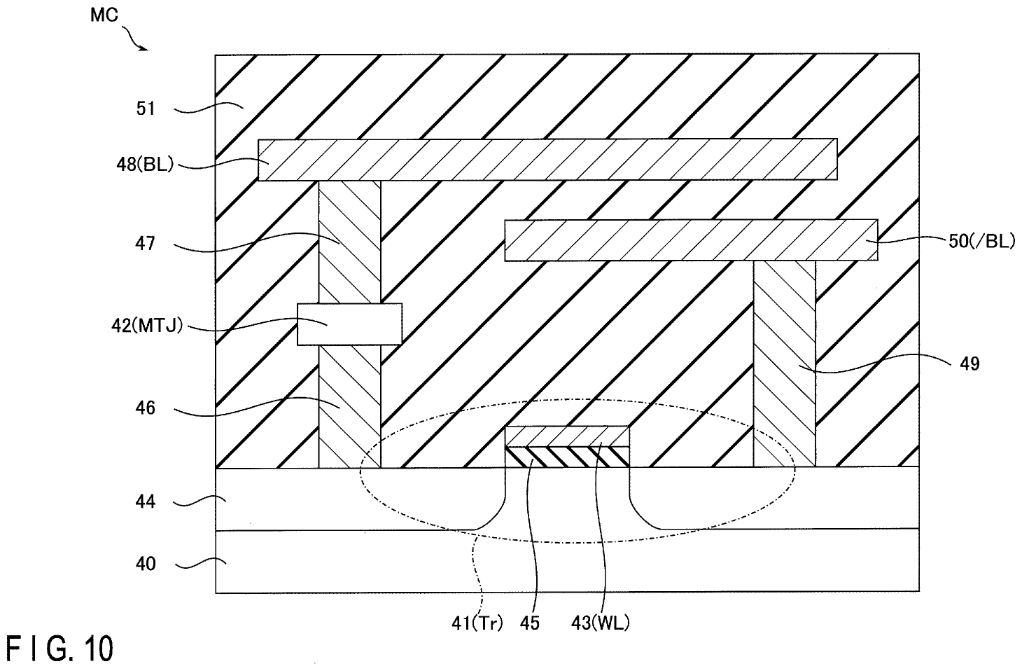

FIG. 10 is a cross-sectional view illustrating a configuration of a memory cell of a magnetic memory device according to a modification. FIG. 10 shows a structure corresponding to the memory cell MC of the first embodiment shown in FIG. 3 and FIG. 4. Since the memory cell MC of the example shown in FIG. 10 is not stacked on a semiconductor substrate, additional symbols, such as “u” and “d”, are not used.

As shown in FIG. 10, the memory cell MC is provided on the semiconductor substrate 40 and includes a select transistor 41 (Tr) and a magnetoresistive effect element 42 (MTJ). The select transistor 41 is provided as a switch for controlling supply and stopping of a current at the time of data write to and data read from the magnetoresistive effect element 42. The configuration of the magnetoresistive effect element 42 is the same as that of the magnetoresistive effect element MTJ of the first embodiment shown in FIG. 5.

The select transistor 41 includes a gate (conductor 43) that serves as a word line WL, and a pair of source and drain regions (diffusion regions 44) provided on both sides of the gate in the x direction in a surface portion of the semiconductor substrate 40. The conductor 43 is provided on an insulator 45 that functions as a gate insulation film provided on the semiconductor substrate 40. The conductor 43 extends, for example, in the y direction, and is commonly coupled to a gate of a select transistor (not shown) of another memory cell MC arranged alongside in the y direction. The conductors 43 are arranged side by side, for example, in the x direction. A contact plug 46 is provided on the source region 44 at a first end of the select transistor 41. The contact plug 46 is coupled to a lower surface (first end) of the magnetoresistive effect element 42. A contact plug 47 is provided on an upper surface (second end) of the magnetoresistive effect element 42, and an upper surface of the contact plug 47 is coupled to a conductor 48 that functions as a bit line BL. The conductor 48 extends, for example, in the x direction, and is commonly coupled to the second end of the magnetoresistive effect element (not shown) of another memory cell arranged alongside in the x direction. A contact plug 49 is provided on the source region 44 at a second end of the select transistor 41. The contact plug 49 is coupled to a lower surface of a conductor 50 that functions as the source line /BL. The conductor 50 extends, for example, in the x direction, and is commonly coupled to the second end of the select transistor (not shown) of another memory cell arranged alongside in the x direction. The conductors 48 and 50 are arranged, for example, in the y direction. The conductor 48 is, for example, located above the conductor 50. The conductors 48 and 50 are arranged to avoid physical and electric interference with each other, although this is not specifically shown in FIG. 10. The select transistor 41, the magnetoresistive effect element 42, the conductors 43, 48, and 50, and the contact plugs 46, 47, and 49 are covered with an interlayer insulation film 51. The other magnetoresistive effect elements 42 (not shown) arranged along the x direction or the y direction relative to the magnetoresistive effect element are, for example, provided on the same level. That is, in the memory cell array 10A, a plurality of magnetoresistive effect elements 42 are arranged, for example, in the XY plane.

With the configuration described above, in the case of applying a MOS transistor, which is a three-terminal type switching element, as the switching element SEL, instead of the two-terminal type switching element, the same advantages as those of the first embodiment can be attained.

In the memory cell MC of the embodiment and modification described above, the magnetoresistive effect element MTJ is provided under the switching element SEL. However, the magnetoresistive effect element MTJ may be provided above the switching element SEL.

Furthermore, in the above first embodiment and the modifications, the magnetic memory device that includes the MTJ element is described as an example of a magnetic device that includes a magnetoresistive effect element; however, the configuration is not limited thereto. For example, the magnetic device may include another device that requires a magnetic element having a perpendicular magnetic anisotropy, such as a sensor and a medium. The magnetic element is, for example, an element that includes at least the nonmagnet 31, the nonmagnet 32, the nonmagnet 33, the ferromagnet 34, and the nonmagnet 35 shown in FIG. 5.

While certain embodiments have been described, these embodiments have been presented by way of example only, and are not intended to limit the scope of the inventions/present disclosure. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit.

What is claimed is:

1. A magnetic device comprising:
a magnetoresistive effect element,
the magnetoresistive effect element including:
a first nonmagnet;
a second nonmagnet;
a first ferromagnet between the first nonmagnet and the second nonmagnet;
a third nonmagnet including a rare-earth oxide, the second nonmagnet between the first ferromagnet and the third nonmagnet; and
a fourth nonmagnet between the second nonmagnet and the third nonmagnet and including a metal.

2. The device of claim 1, wherein the fourth nonmagnet includes at least one element selected from tantalum (Ta), hafnium (Hf), zirconium (Zr), titanium (Ti), vanadium (V), and niobium (Nb).

3. The device of claim 2, wherein the fourth nonmagnet further includes boron (B).

4. The device of claim 1, wherein the fourth nonmagnet has a thickness of two nanometers or smaller.

5. The device of claim 1, wherein the fourth nonmagnet has a resistance value that is a tenth or less of a resistance value of the first nonmagnet.

6. The device of claim 1, wherein the first nonmagnet and the second nonmagnet include magnesium oxide (MgO).

7. The device of claim 6, wherein the second nonmagnet further includes boron (B).

8. The device of claim 6, wherein a thickness of the second nonmagnet is smaller than a thickness of the first nonmagnet.

9. The device of claim 8, wherein the second nonmagnet has the thickness of 1 nanometer or smaller.

10. The device of claim 1, wherein the third nonmagnet includes at least one element selected from scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

11. The device of claim 1, wherein the first ferromagnet includes at least one element selected from iron (Fe), cobalt (Co), and nickel (Ni).

12. The device of claim 11, wherein:
the magnetoresistive effect element further includes a second ferromagnet, the first nonmagnet between the first ferromagnet and the second ferromagnet; and
the first ferromagnet has
a first resistance value in accordance with a first current from the first ferromagnet to the second ferromagnet, and
a second resistance value in accordance with a second current from the second ferromagnet to the first ferromagnet.

13. The device of claim 12, wherein the second ferromagnet includes at least one element selected from iron (Fe), cobalt (Co), and nickel (Ni).

14. The device of claim 12, wherein the first resistance value is smaller than the second resistance value.

15. The device of claim 12, wherein the first ferromagnet is above the second ferromagnet.

16. The device of claim 15, wherein the second nonmagnet is under the fourth nonmagnet.

17. The device of claim 12, comprising a memory cell, the memory cell including:
the magnetoresistive effect element; and
a switching element coupled in series to the magnetoresistive effect element.
